(19) United States
(12) Patent Application Publication
(10) Pub. No.: US 2026/0135191 A1
(43) Pub. Date: May 14, 2026

(54) IMMERSION LIQUID-COOLING DEVICE, ENERGY STORAGE SYSTEM AND HEAT MANAGEMENT METHOD

(71) Applicant: Zhejiang Jinko Energy Storage Co., Ltd., Haining (CN)

(72) Inventor: Junyun WEN, Haining (CN)

(21) Appl. No.: 19/362,314

(22) Filed: Oct. 17, 2025

(30) Foreign Application Priority Data
Nov. 14, 2024 (CN) 202411629231.9

(51) Int. Cl. H01M 10/6568; H01M 10/613; H01M 10/63; H05K 7/20

(52) U.S. Cl. CPC H01M 10/6568; H01M 10/613; H01M 10/63; H05K 7/20236

(57) ABSTRACT

The present disclosure provides an immersion liquid-cooling device, an energy storage system, and a heat management method. The immersion liquid-cooling device includes a box body, and a fluid circulation structure. The box body has plurality of liquid-cooling spaces sequentially formed along a predetermined direction, and each liquid-cooling space is configured to accommodate at least one respective battery module. The fluid circulation structure is connected to the box body and includes a liquid-inlet pipeline for supplying coolant, a series-flow pipeline for transferring the coolant, and a liquid-outlet pipeline for discharging the coolant. One of two distal liquid-cooling spaces of the plurality of liquid-cooling spaces in the predetermined direction is in fluid communication with the liquid-inlet pipeline, the other of the two distal liquid-cooling spaces is in fluid communication with the liquid-outlet pipeline, and every two adjacent liquid-cooling spaces are in fluid communication with each other through the series-flow pipeline.

### CROSS REFERENCE TO RELATED APPLICATIONS

The present application claims the benefit of priority under the Paris Convention to Chinese Patent Application No. 202411629231.9 filed on Nov. 14, 2024, which is incorporated herein by reference in its entirety.

### TECHNICAL FIELD

The embodiments of the present disclosure relate to the technical field of heat dissipation for energy storage systems, and in particular to an immersion liquid-cooling device, an energy storage system, and a heat management method.

### BACKGROUND

With the continuous development of industrial technology, the demand for energy is increasing, and various new energy sources have been widely and practically applied. The importance of energy storage is also gradually increasing. An energy storage system can store electrical energy using battery modules and output the stored electrical energy when needed. Since the energy storage system needs to be controlled at an appropriate temperature during operation, it is necessary to dissipate heat from the energy storage system.

The energy storage system generally contains a large number of battery modules, and the temperature of these battery modules during operation determines the working performance of the energy storage system.

### SUMMARY

The embodiments of the present disclosure provide an immersion liquid-cooling device, an energy storage system, and a heat management method, which are beneficial to control of the temperatures of the battery modules in the energy storage system.

The immersion liquid-cooling device includes a box body, and a fluid circulation structure. The box body has a plurality of liquid-cooling spaces sequentially formed along a predetermined direction and isolated from each other, each liquid-cooling space of the plurality of liquid-cooling spaces is configured to accommodate at least one respective battery module. The fluid circulation structure is connected to the box body and includes a liquid-inlet pipeline for supplying a coolant, a series-flow pipeline for transferring the coolant, and a liquid-outlet pipeline for discharging the coolant; one of two distal liquid-cooling spaces of the plurality of liquid-cooling spaces in the predetermined direction is in fluid communication with the liquid-inlet pipeline, the other of the two distal liquid-cooling spaces is in fluid communication with the liquid-outlet pipeline, and every two adjacent liquid-cooling spaces of the plurality of liquid-cooling spaces are in fluid communication with each other through the series-flow pipeline.

The embodiments of the present disclosure further provide an energy storage system including a plurality of battery modules and the above-mentioned immersion liquid-cooling device. Each battery module of the plurality of battery modules includes a plurality of cells. Each liquid-cooling space of the plurality of liquid-cooling spaces of the box body is configured to accommodate at least one respective battery module of the plurality of battery modules.

The embodiments of the present disclosure further provide a heat management method applied to the above-mentioned immersion liquid-cooling device, including:

injecting the coolant into the plurality of liquid-cooling spaces of the box body through the fluid circulation structure until a liquid level of the coolant reaches an initial liquid level;

detecting temperatures of a plurality of cells of the at least one respective battery module in each liquid-cooling space of the plurality of liquid-cooling spaces;

in response to the temperatures of the plurality of cells going out of a threshold range, rising the liquid level of the coolant in the plurality of liquid-cooling spaces by controlling the plurality of fluid distribution units to distribute using the fluid control unit; and

in response to the temperatures of the plurality of cells not going out of the threshold range, maintaining the liquid level of the coolant in the plurality of liquid-cooling spaces at the initial liquid level.

In the immersion liquid-cooling device, the energy storage system and the heat management method provided in the embodiments of the present disclosure, the plurality of liquid-cooling spaces are formed in the box body, and each liquid-cooling space accommodates respective battery modules. Each liquid-cooling space is connected to the coolant circulation system through the fluid circulation structure, and the coolant can enter the box body through the liquid-inlet pipeline, and continuously circulate among the liquid-cooling spaces through the series-flow pipeline to reach a certain immersion liquid-level height. The coolant takes away the heat of the cells of the battery modules during circulation, thereby realizing sufficient heat dissipation for the battery modules. In addition, the liquid-level heights of the immersion coolant in the liquid-cooling spaces where the battery modules are located can be adjusted individually using the fluid control unit cooperating with the fluid distribution units, so that the heat dissipation capacity of the liquid-cooling spaces where the battery modules are located can be adjusted individually, thereby controlling the temperatures of the battery modules in the energy storage system.

In some embodiments, the immersion liquid-cooling device further includes a liquid level adjustment structure connected to the box body. The liquid level adjustment structure includes a distribution pipeline in fluid communication with the plurality of liquid-cooling spaces, a fluid control unit, and a plurality of fluid distribution units. The fluid control unit and the plurality of fluid distribution units are arranged on the distribution pipeline, the plurality of fluid distribution units are in one-to-one correspondence to the plurality of liquid-cooling spaces, each fluid distribution unit of the plurality of fluid distribution units is configured to distribute the coolant to a respective liquid-cooling space, and the fluid control unit is configured to control an amount of the coolant distributed by each fluid distribution unit to the respective liquid-cooling space and to adjust a liquid level in the respective liquid-cooling space.

In some embodiments, the liquid-inlet pipeline and the liquid-outlet pipeline are arranged on one of two lateral surfaces of the box body extending along a first direction or are arranged on the two lateral surfaces, respectively, and the first direction is perpendicular to an arrangement direction of a plurality of cells of the at least one respective battery module. In this way, the coolant can flow in and be discharged along the arrangement direction of the plurality of cells of the at least one respective battery module, thereby ensuring the heat dissipation effect on the plurality of cells of the at least one respective battery module.

In some embodiments, the fluid circulation structure includes a plurality of series-flow pipelines, each series-flow pipeline of the plurality of series-flow pipelines is configured to communicate two respective liquid-cooling spaces of the plurality of liquid-cooling spaces that are adjacent in the predetermined direction, and the plurality of series-flow pipelines are alternately arranged on the two lateral surfaces of the box body. In this way, the coolant can flow in a unidirectional and serpentine way through the plurality of liquid-cooling spaces, thereby ensuring that the coolant can sequentially absorb the heat from the battery modules in the plurality of liquid-cooling spaces.

In some embodiments, the fluid circulation structure includes a plurality of liquid-inlet pipelines, a plurality of liquid-outlet pipelines, and a plurality of series-flow pipelines that are arranged at intervals along the first direction, respectively. In this way, the number of pipelines of the fluid circulation structure can be increased, thereby increasing the flow paths of the coolant, and ensuring the stable flow of the coolant.

In some embodiments, the box body includes a frame, walls arranged on the frame and forming an enclosed space, and separators dividing the enclosed space into the plurality of liquid-cooling spaces. The frame has a plurality of platforms in one-to-one correspondence to the plurality of liquid-cooling spaces, each platform of the plurality of platforms has a respective hollow area and is configured to support the at least one respective battery module and separate the at least one respective battery module from a corresponding separator of the separators. In this way, the plurality of platforms having the hollow areas can allow the bottoms of the battery modules to be in contact with the immersion coolant for heat exchange, thereby improving the heat dissipation effect of the coolant.

In some embodiments, the frame includes a plurality of columns abutting on the walls, respectively, a plurality of connecting rod assemblies arranged along the predetermined direction and respectively connecting to the plurality of columns, and intermediate rod assemblies in one-to-one correspondence to the plurality of liquid-cooling spaces. Each intermediate rod assembly of the intermediate rod assemblies is connected to a respective connecting rod assembly of the plurality of connecting rod assemblies and includes a respective plurality of intermediate rods arranged at intervals and configured to support the at least one respective battery module, and an extending direction of the respective plurality of intermediate rods is parallel to an arrangement direction of a plurality of cells of the at least one respective battery module. In this way, by forming the frame with a frame-type structure, the bottoms of the battery modules can be ensured to be in full contact with the coolant for heat exchange, thereby ensuring the heat dissipation capacity for the battery modules and the stable support of the battery modules.

In some embodiments, the frame further includes reinforcing rib assemblies in one-to-one correspondence to the plurality of liquid-cooling spaces, each reinforcing rib assembly of the reinforcing rib assemblies is connected to a respective intermediate rod assembly of the intermediate rod assemblies and includes a respective plurality of reinforcing ribs arranged at intervals, and each reinforcing rib of the respective plurality of reinforcing ribs is flush with or lower than the respective plurality of intermediate rods in the predetermined direction. In this way, the structural strengths of the platforms of the frame can be enhanced using the reinforcing ribs without affecting the arrangement of the battery modules.

In some embodiments, the fluid circulation structure further includes a liquid replenishment pipeline, and the liquid replenishment pipeline and the liquid-inlet pipeline are connected to a same liquid-cooling space of the plurality of liquid-cooling spaces. In this way, the coolant can be replenished using the liquid replenishment pipeline, thereby effectively increasing the total volume of the coolant circulating in the box body, so as to improve the heat dissipation capacity of the coolant.

### BRIEF DESCRIPTION OF THE DRAWINGS

Exemplary illustrations of one or more embodiments are provided by reference to pictures in the corresponding accompanying drawings. These exemplary illustrations do not constitute a limitation on the embodiments. Elements with the same reference numerals in the drawings represent similar elements, and the drawings do not constitute a scale limitation unless otherwise specified.

FIG. 1 is a schematic diagram of a three-dimension structure of an energy storage system provided in some embodiments of the present disclosure.

FIG. 2 is a right view of the structure of the energy storage system provided in some embodiments of the present disclosure.

FIG. 3 is a schematic diagram of an internal structure of the energy storage system provided in some embodiments of the present disclosure.

FIG. 4 is a schematic diagram showing the arrangement of the battery modules in the energy storage system provided in some embodiments of the present disclosure.

FIG. 5 is a schematic diagram of a three-dimension structure of a frame in the energy storage system provided in some embodiments of the present disclosure.

FIG. 6 is a flowchart of a heat management method for an immersion liquid-cooling device in the energy storage system provided in some embodiments of the present disclosure.

### DETAILED DESCRIPTION OF THE EMBODIMENTS

In order to make the object, technical solutions and advantages of the embodiments of the present disclosure clearer, the embodiments of the present disclosure will be illustrated in the following, with reference to the accompanying drawings. Those skilled in the art shall understand that in the embodiments of the present disclosure, many technical details are put forward to make readers better understand the present disclosure. However, even without these technical details and various changes and modifications based on the following embodiments, the technical solutions claimed in the present disclosure can be realized. The following embodiments are illustrated individually for the convenience of description, but do not suggest any limitation on the specific implementation of the present disclosure. The embodiments can be combined with each other and referred to without contradiction.

Unless otherwise defined, all technical and scientific terms used herein have the same meaning as commonly understood by those skilled in the art to which the present disclosure belongs. The terms used herein are for the purpose of describing specific embodiments only and are not intended to limit the present disclosure. The terms “include” and “have” and any variations thereof in the specification and claims of the present disclosure and the above description of the drawings are intended to refer to non-exclusive inclusion.

In the description of the embodiments of the present disclosure, unless otherwise specified and limited, technical terms such as “install”, “interconnect”, and “connect” should be broadly understood. For example, it may be a fixed connection, a detachable connection or an integrated connection, it may also be a mechanical connection or an electrical connection, it may be a direct connection, or an indirect connection through an intermediate medium, may be the internal connection between two elements or the interaction between two elements. For those skilled in the art, the specific meanings of the above terms in the embodiments of the present disclosure can be understood according to the specific situations.

The effective utilization of energy is inseparable from energy storage systems. An energy storage system can effectively store the electrical energy converted by a power generation system and release the stored electrical energy as required by the power consumption system. With the energy storage systems, the waste of electrical energy generated by the power generation system during off-peak power consumption period can be prevented, and the shortage of power supply in power consumption system during peak power consumption period can be addressed. The battery modules in an energy storage system contain a large number of cells. By connecting the large number of cells in series or in parallel, energy can be stored as much as possible.

Currently, most energy storage systems use liquid-cooling plates for cooling. However, limited by the heat dissipation capacity of liquid-cooling plates, battery modules generally suffer from uneven distribution of temperatures of the internal cells and excessive temperature rise in some cells. These problems greatly reduce the working efficiency of the energy storage systems. Therefore, a new heat dissipation device for the energy storage systems is needed.

In order to individually control the temperatures of the battery modules in the energy storage system, some embodiments of the present disclosure provide an immersion liquid-cooling device. The immersion liquid-cooling device uses immersion liquid cooling in clusters, the battery modules are immersed in the coolant, and the cells of the battery modules can fully contact with the coolant to exchange heat and realize heat dissipation. In addition, the liquid-level heights of the immersion coolant corresponding to the battery modules can be adjusted individually, so that the heat dissipation capacity can be adjusted by individually adjusting the liquid-level heights of the immersion coolant for the battery modules. In this way, the temperatures of the battery modules can be controlled individually.

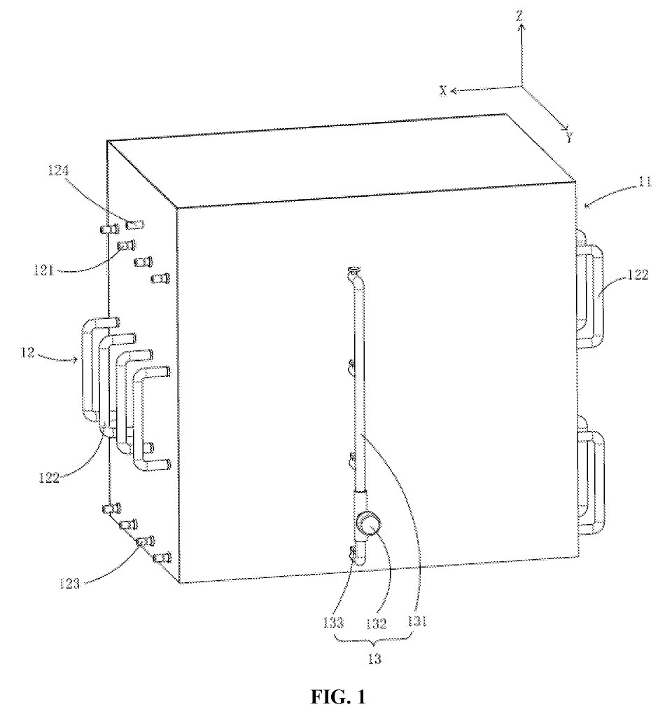

In the following, the structure of the immersion liquid-cooling device in the energy storage system provided in some embodiments of the present disclosure will be described with reference to FIG. 1 to FIG. 5.

As shown in FIG. 1 to FIG. 5, the immersion liquid-cooling device provided in some embodiments of the present disclosure includes a box body 11, and a fluid circulation structure 12. The box body 11 has a plurality of liquid-cooling spaces 101 sequentially formed along a predetermined direction (the direction indicated by arrow Z in FIG. 1) and isolated from each other, and each liquid-cooling space 101 is configured to accommodate at least one respective battery module 21. The fluid circulation structure 12 is connected to the box body 11. The fluid circulation structure 12 includes a liquid-inlet pipeline 121, a series-flow pipeline 122 and a liquid-outlet pipeline 123. The liquid-inlet pipeline 121 is configured to supply a coolant, the series-flow pipeline 122 is configured to transfer the coolant, and the liquid-outlet pipeline 123 is configured to discharge the coolant. One of two distal liquid-cooling spaces 101 in the predetermined direction is in fluid communication with the liquid-inlet pipeline 121, and the other distal liquid-cooling space is in fluid communication with the liquid-outlet pipeline 123. Every two adjacent liquid-cooling spaces 101 are in fluid communication with each other through the series-flow pipeline 122.

The immersion liquid-cooling device further includes a liquid level adjustment structure 13 connected to the box body 11. The liquid level adjusting structure 13 includes a distribution pipeline 131 in fluid communication with the plurality of liquid-cooling spaces 101, and further includes a fluid control unit 132 and a plurality of fluid distribution units 133. The fluid control unit 132 and the plurality of fluid distribution units 133 are arranged on the distribution pipeline 131. The plurality of fluid distribution units 133 are in one-to-one correspondence to the plurality of liquid-cooling spaces 101, each fluid distribution unit 133 is configured to distribute the coolant to a respective liquid-cooling space 101, and the fluid control unit 132 is configured to control an amount of the coolant distributed by each fluid distribution unit 133 to the respective liquid-cooling space 101 and to adjust a liquid level in the respective liquid-cooling space 101.

The box body 11 provides an accommodation space for assembling the energy storage system. The battery modules 21 may be fixed at different positions inside the box body 11. In order to achieve immersion liquid cooling for the battery modules 21, the plurality of liquid-cooling spaces 101 are provided inside the box body 11, and each liquid-cooling space 101 is relatively enclosed. After injected into the liquid-cooling spaces 101, the coolant may partially or completely immerse the battery modules 21. In the immersion state by the coolant, the cells 211 of the battery modules 21 can fully contact with the coolant to achieve heat dissipation. Each liquid-cooling space 101 may accommodate one or more battery modules 21. The plurality of liquid-cooling spaces 101 are sequentially formed along the predetermined direction, where the predetermined direction may be a vertical direction, a horizontal direction, or other directions forming an included angle with the vertical direction. In practice, the plurality of liquid-cooling spaces 101 may be formed in layers or separated from each other. The overall shape of the box body 11 may be a regular shape such as a cube, a cuboid, or a cylinder, or the box body 11 may have an irregular special shape. The liquid-cooling spaces 101 inside the box body 11 may have regular shapes such as cubes, cuboids, or cylinders, or may have irregular special shapes.

The fluid circulation structure 12 is configured to facilitate the connection of the coolant circulation system to the internal space of the box body 11. The fluid circulation structure 12 includes a liquid-inlet pipeline 121 for inputting the coolant to the liquid-cooling spaces 101 of the box body 11, a series-flow pipeline 122 for transferring the coolant between two adjacent liquid-cooling spaces 101, and a liquid-outlet pipeline 123 for discharging the coolant. One end of the liquid-inlet pipeline 121 protruding from the box body 11 may be connected to a pipeline for supplying the coolant, and the other end of the liquid-inlet pipeline 121 is in fluid communication with one of the two distal liquid-cooling spaces 101 which are the farthest apart in the predetermined direction. One end of the liquid-outlet pipeline 123 protruding from the box body 11 may be connected to a pipeline for recovering the coolant, and the other end of the liquid-outlet pipeline 123 is in fluid communication with the other one of the two distal liquid-cooling spaces 101 that are the farthest apart in the predetermined direction. Two ends of the series-flow pipeline 122 are in fluid communication with two adjacent liquid-cooling spaces 101. The plurality of liquid-cooling spaces 101 are in fluid communication with each other through the series-flow pipelines 122, so that the circulating coolant can reach each liquid-cooling space 101 of the box body 11. In practice, the plurality of liquid-cooling spaces 101 may be sequentially connected through the series-flow pipelines 122, so that the coolant flows through the plurality of liquid-cooling spaces 101 in sequence. Alternatively, when a large number of liquid-cooling spaces 101 are provided, some liquid-cooling spaces 101 may be in fluid communication with two or more other liquid-cooling spaces 101, so that the coolant can be concurrently distributed to two or more liquid-cooling spaces 101 during circulating. The connection positions of each pipeline of the fluid circulation structure 12 on the box body 11 may be determined according to actual needs. In order to ensure the flow effect of the coolant in each liquid-cooling space 101, the connection positions of each pipeline may be close to the bottom of the corresponding liquid-cooling space 101.

The liquid level adjustment structure 13 is configured to adjust the liquid-level height of the immersion coolant in each liquid-cooling space 101 of the box body 11. The liquid level adjustment structure 13 includes a distribution pipeline 131 in fluid communication with the plurality of liquid-cooling spaces 101. A fluid control unit 132 and fluid distribution units 133 in one-to-one correspondence to the plurality of liquid-cooling spaces 101 are arranged on the distribution pipeline 131. The fluid distribution units 133 can control the flow rate of the coolant flowing through where the fluid distribution units are arranged, and the fluid control unit 132 can control the flow of the coolant. Each of the fluid distribution units 133 may be a solenoid valve, a throttle valve, or a flow control valve with an adjustable opening. The fluid control unit 132 may be a pump, such as a positive-displacement pump, a vane pump, or a centrifugal pump.

When the energy storage system detects that the temperature of the cells 211 of a certain battery module 21 is too high, the liquid level adjustment structure 13 may be used to actively adjust the liquid-level height of the immersion coolant in the liquid-cooling space 101 where the battery module 21 is arranged, so that the liquid-level height of the coolant in the liquid-cooling space 101 where the battery module 21 is arranged is raised. Therefore, the heat dissipation capacity of the liquid-cooling space 101 is improved, and the temperature of the cells 211 of the battery module 21 is controlled to remain within a reasonable range.

In the immersion liquid-cooling device provided in some embodiments of the present disclosure, the plurality of liquid-cooling spaces 101 are formed in the box body 11, and each liquid-cooling space 101 accommodates respective battery modules 21. Each liquid-cooling space 101 is connected to the coolant circulation system through the fluid circulation structure 12, and the coolant can enter the box body 11 through the liquid-inlet pipeline 121, and continuously circulate among the liquid-cooling spaces 101 through the series-flow pipeline 122 to reach a certain immersion liquid-level height. The coolant takes away the heat of the cells 211 of the battery modules 21 during circulation, thereby realizing sufficient heat dissipation for the battery modules 21. In addition, the liquid-level heights of the immersion coolant in the liquid-cooling spaces 101 where the battery modules 21 are located can be adjusted individually using the fluid control unit 132 cooperating with the fluid distribution units 133, so that the heat dissipation capacity of the liquid-cooling spaces 101 where the battery modules 21 are located can be adjusted individually, thereby controlling the temperatures of the battery modules 21 in the energy storage system.

In some embodiments, the liquid-inlet pipeline 121 and the liquid-outlet pipeline 123 may be arranged on one of two lateral surfaces of the box body extending along a first direction (the direction indicated by the arrow Y in FIG. 1) or are arranged on the two lateral surfaces, respectively. The first direction is perpendicular to an arrangement direction (the direction indicated by the arrow X in FIG. 1) of a plurality of cells 211 of the at least one respective battery module 21.

The liquid-inlet pipeline 121 is configured to control the inflow of the coolant to the liquid-cooling spaces 101 inside the box body 11, and the liquid-outlet pipeline 123 is configured to control the outflow of the coolant from the liquid-cooling spaces 101 inside the box body 11. By arranging the liquid-inlet pipeline 121 and the liquid-outlet pipeline 123 on a same lateral surface of the box body or on the two lateral surfaces, respectively, the flow direction of the coolant during inflow and outflow can be consistent with the arrangement direction of the plurality of cells 211 of the at least one respective battery module 21, so that the coolant can be controlled to flow inside the box body 11 along the arrangement direction of the plurality of cells 211 of the at least one respective battery module 21, thereby ensuring the heat dissipation effect for the cells 211 of the at least one respective battery module 21.

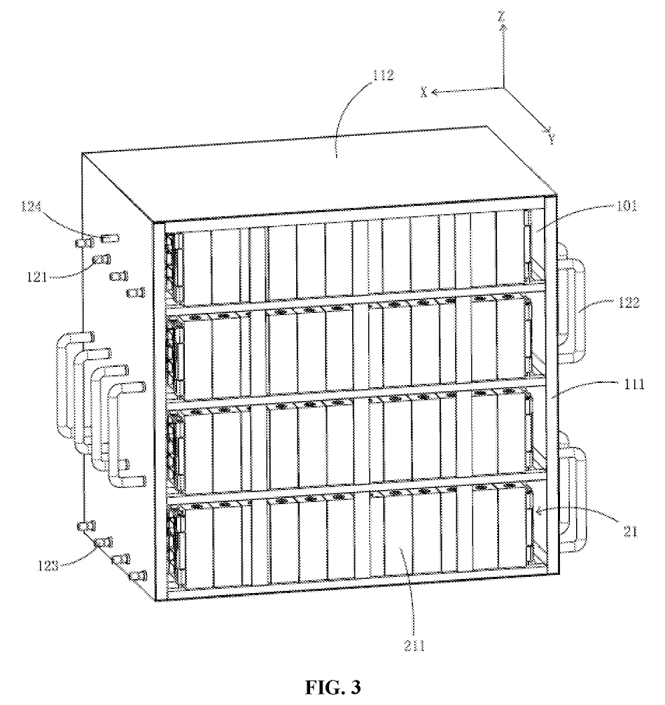

When the number of liquid-cooling spaces 101 is even, the liquid-inlet pipeline 121 and the liquid-outlet pipeline 123 may be arranged on a same lateral surface of the box body 11. When the number of liquid-cooling spaces 101 is odd, the liquid-inlet pipeline 121 and the liquid-outlet pipeline 123 may be arranged on the two lateral surfaces of the box body 11, respectively. As shown in FIG. 3, the box body 11 is provided with four liquid-cooling spaces 101. The liquid-inlet pipeline 121 and the liquid-outlet pipeline 123 are arranged on a same lateral surface of the box body 11, and the end of the liquid-inlet pipeline 121 and the end of the liquid-outlet pipeline 123 that are connected to the liquid-cooling spaces 101 face the two surfaces of the cells 211 of the battery modules 21 having relatively large areas, that is, face the arrangement direction of the plurality of cells 211.

In practice, in order to ensure that the coolant fully contacts with each cell 211 of the battery modules 21 and smoothly flows through each liquid-cooling space 101, an end of the series-flow pipeline 122 that receives the coolant may be arranged on the downstream side of the coolant flowing in each liquid-cooling space 101, and an end of the series-flow pipeline 122 from which the coolant flows out may be arranged on the upstream side of the coolant flowing in each liquid-cooling space 101. Moreover, when the liquid-cooling spaces 101 are arranged in layers, the liquid-inlet pipeline 121 may be arranged at or close to the top of the box body 11, and the liquid-outlet pipeline 123 may be arranged at or close to the bottom of the box body 11, so that the coolant can smoothly flow through the liquid-cooling spaces 101 of the box body 11 under the action of gravity.

In some embodiments, the fluid circulation structure includes a plurality of series-flow pipelines 122. Each series-flow pipeline 122 is configured to communicate two respective liquid-cooling spaces 101 that are adjacent in the predetermined direction, and in the predetermined direction, the plurality of series-flow pipelines 122 are alternately arranged on the two lateral surfaces of the box body 11 extending along the first direction.

When more than two liquid-cooling spaces 101 are provided in the box body 11, more than two series-flow pipelines 122 may be provided to take the plurality of liquid-cooling spaces 101 into communication with each other. Every two adjacent liquid-cooling spaces 101 may be communicated by one series-flow pipeline 122, and in the predetermined direction, the plurality of series-flow pipelines 122 are alternately arranged on the two lateral surfaces of the box body 11. In this way, the plurality of liquid-cooling spaces 101 are connected in an end-to-end way. After injected into the box body 11, the coolant can flow in the box body 11 in a serpentine way, thereby realizing full contact of the coolant with each battery module 21, and effectively taking away the heat from the cells 211 of each battery module 21.

In some embodiments, the fluid circulation structure includes a plurality of liquid-inlet pipelines 121, a plurality of liquid-outlet pipelines 123, and a plurality of series-flow pipelines 122 that are arranged at intervals along the first direction, respectively.

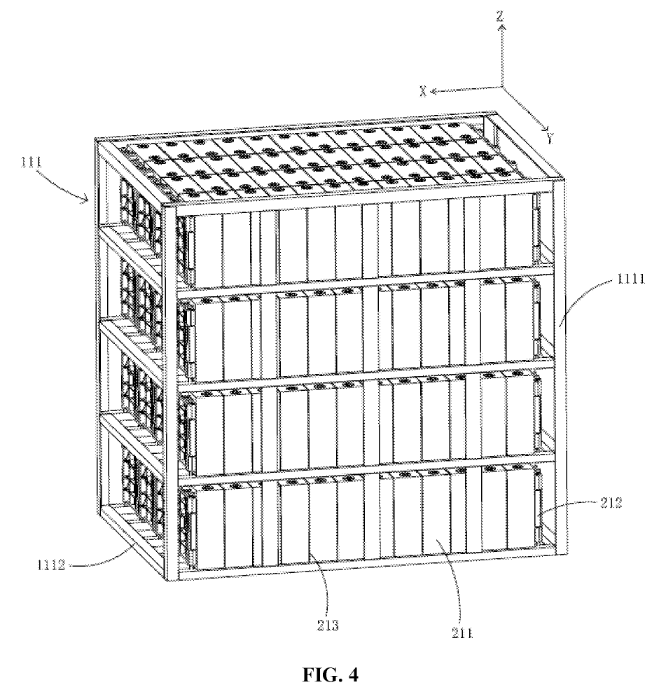

The liquid-cooling spaces 101 inside the box body 11 generally have relatively large volumes to accommodate one or more battery modules 21. The battery modules 21 may be arranged in parallel, sequentially, or in an array in the liquid-cooling spaces 101. In order to adapt to the size of the space inside the box body 11, the number of pipelines of the fluid circulation structure 12 may be increased. Thus, the plurality of liquid-inlet pipelines 121, the plurality of liquid-outlet pipelines 123, and the plurality of series-flow pipelines 122 are provided. Furthermore, the plurality of liquid-inlet pipelines 121, the plurality of liquid-outlet pipelines 123, and the plurality of series-flow pipelines 122 are arranged at intervals along the first direction, respectively. In other words, these pipelines are arranged along an apposition direction of the plurality of battery modules 21. In this way, the coolant flowing in the liquid-cooling spaces 101 can fully immerse the areas where the battery modules 21 are arranged, thereby realizing uniform heat dissipation for each battery module 21 in a same liquid-cooling space 101, and ensuring that a sufficient amount of coolant can continuously flow into the liquid-cooling spaces 101 of the box body 11. In practice, the number of pipelines of the fluid circulation structure 12 may be consistent with the number of the apposed battery modules 21 in each liquid-cooling space 101. For example, each liquid-cooling space 101 of the box body 11 shown in FIG. 3 and FIG. 4 may accommodate four battery modules 21 arranged side-by-side, and the fluid circulation structure 12 may include four corresponding liquid-inlet pipelines 121, four liquid-outlet pipelines 123, and four series-flow pipelines 122 for communicating adjacent liquid-cooling spaces 101. The four battery modules 21 are arranged at intervals, and the coolant may flow along the side surfaces of each battery module 21, so as to take away the heat from each battery module 21.

In addition, when the battery modules 21 are arranged in the liquid-cooling spaces 101 inside the box body 11, a certain space may be reserved under the bottom of each battery module 21, so that the coolant can contact with the bottoms of the battery modules 21 after being injected into the liquid-cooling spaces 101, thereby ensuring the contact area between the coolant and the cells 211 of the battery modules 21 and realizing effective heat transfer. That is, the battery modules 21 may be arranged on platforms 102 having hollow areas.

In some embodiments, the box body 11 may include a frame 111, walls 112 arranged on the frame 111 and forming an enclosed space, and separators 113 dividing the enclosed space into the plurality of liquid-cooling spaces 101. The frame 111 has a plurality of platforms 102 in one-to-one correspondence to the plurality of liquid-cooling spaces 101. Each platform 102 has a respective hollow area and is configured to support the at least one respective battery module 21 and separate the at least one respective battery module 21 from a corresponding separator 113.

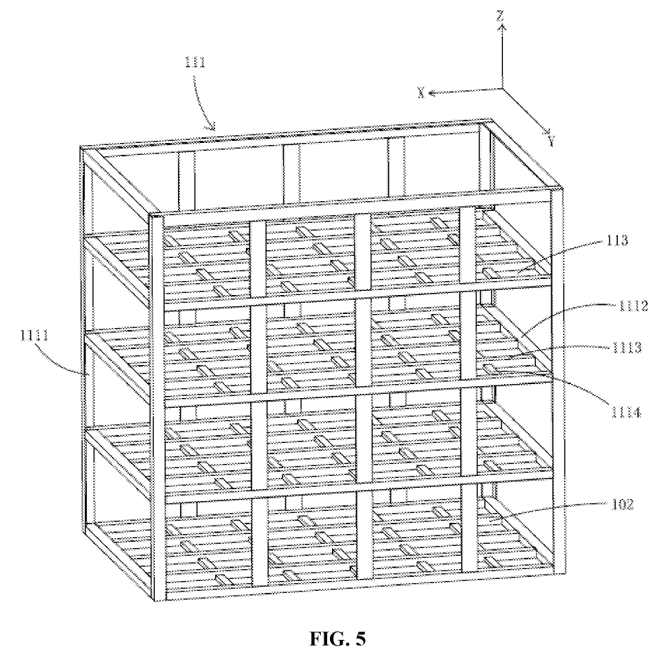

The frame 111 is configured to form platforms 102 for arranging the battery modules 21 in the box body 11. The frame 111 may be a frame-type component and is made by splicing and assembling. In order to ensure the structural strength of the frame 111, the frame 111 may be made of metal. The walls 112 are arranged on an outer contour of the frame 111. The internal accommodation space of the box body 11 may be enclosed by the walls 112, so that the battery modules 21 are arranged in a closed environment relative to the external environment. The separators 113 divides the enclosed space formed by the walls 112 into the plurality of liquid-cooling spaces 101. The separators 113 may be in the form of flat plates and may be connected and fixed to the walls 112 or the frame 111. Each liquid-cooling space 101 is kept in a relatively closed state by the separators 113. As shown in FIG. 5, the separators 113 are arranged on the three intermediate platforms 102 of the frame 111, respectively. The three separators 113 cooperate with the walls 112 to form four relatively closed liquid-cooling spaces 101. The relatively closed liquid-cooling spaces 101 are in fluid communication with each other through the series-flow pipelines 122 to form a complete flow channel for the coolant.

The platforms 102 provided by the frame 111 are in one-to-one correspondence to the liquid-cooling spaces 101, and each platform 102 has a respective hollow area. When the battery modules 21 are fixed on the platforms 102, the bottom of each battery module 21 may be spaced from a corresponding separator 113. In this way, the coolant can enter the hollow areas of the platforms 102 to fully contact with the bottoms of the battery modules 21. Meanwhile, the coolant may also keep in contact with the lateral surfaces of the battery modules 21. As a result, the bottom and the lateral surfaces of each battery module 21 can be in contact with the immersion coolant for heat exchange. In practice, when fixing the battery modules 21, they may be connected to the frame 111 using long bolts. A long bolt may pass through an outermost end plate 212 of a battery module 21 and be fixed on the frame 111, thereby completing the fixation of the battery module 21. There may be a gap between two adjacent cells 211 of a battery module 21 to allow the coolant to be in contact with the peripheries of the cells 211 for heat exchange.

In some embodiments, channels configured for the coolant to flow may be arranged inside the walls 112 of the box body 11, so that the walls 112 enclosing the frame 111 also have heat-absorbing capacity. That is to say, the six walls 112 of the box body 11 shown in FIG. 3 may all be provided with hollow channels. The coolant may be injected into these channels, so that the coolant circulates inside the walls 112 to take away the heat transferred to the walls 112. In order to extend the flow paths of the coolant and ensure sufficient heat absorption by the coolant, each of the channels may have a curved shape. In practice, heat-dissipating components, such as heat pipes, with high efficiency may be provided on the surfaces of the walls or arranged inside the walls 112, so as to conduct the heat transferred from the coolant in the liquid-cooling spaces 101 to the walls 112 to the external environment in time, thereby improving the heat dissipation capacity for the battery modules 21. The heat pipes may be in contact with the walls 112 and the external environment along length directions, or one end of a heat pipe may pass through a wall 112 to contact with the coolant in a liquid-cooling space 101, and the other end contacts with the external environment.

Moreover, each separator may have respective grooves formed on a respective surface of each separator 113 bearing the coolant, and the respective grooves are configured for the coolant to flow. For example, grooves recessed inward may be formed on the surfaces of the separators 113. These grooves may have cross-sectional shapes such as triangles, squares, or rectangles. The coolant may flow along the grooves to reach specific positions in the liquid-cooling spaces 101, which is beneficial to ensuring the flow effect of the coolant at the bottoms of the battery modules 21. Moreover, in order to improve the heat-exchange effect of the coolant, each of the grooves may have a respective curved shape or extend along a respective curved path, thereby prolonging the flow paths of the coolant, and fully absorbing the heat from the battery modules 21.

In addition, as shown in FIG. 4 and FIG. 5, the frame 111 may include a plurality of columns 1111 that abut on the walls 112, respectively, a plurality of connecting rod assemblies 1112 that are arranged along the predetermined direction and respectively connected to the plurality of columns, and intermediate rod assemblies 1113 that are in one-to-one correspondence to the liquid-cooling spaces 101. Each intermediate rod assembly 1113 is connected to a respective connecting rod assembly 1112 and includes a respective plurality of intermediate rods that are arranged at intervals and configured to support the at least one respective battery modules 21. An extending direction of the respective plurality of intermediate rods is parallel to the arrangement direction of the plurality of cells 211 of each battery module 21.

The columns 1111 form the outer contour of the frame 111, and support and abut on the inner surfaces of the walls 112 facing the enclosed space. Each column 1111 extends along the predetermined direction. The plurality of columns 1111 are connected together by the connecting rod assemblies 1112. In the predetermined direction, the connecting rod assemblies 1112 are located at intermediate positions and are located at the tops of the separators 113, respectively. The plurality of connecting rods of each connecting rod assembly 1112 may be connected to each other in an end-to-end way, in order to connect and fix the plurality of columns 1111 along a circumferential direction, thereby ensuring the strength of the formed frame-type structure.

The intermediate rod assemblies 1113 are in one-to-one correspondence to the liquid-cooling spaces 101. Two ends of each intermediate rod of the intermediate rod assemblies 1113 are connected to two respective connecting rods of the connecting rod assemblies 1112, respectively. Moreover, the plurality of intermediate rods of each intermediate rod assembly 1113 are arranged at intervals, and are in contact with only a portion of the surface areas of the battery modules 21 when supporting the battery modules 21. Therefore, relatively large hollow areas are formed below the bottoms of the battery modules 21, thereby facilitating the filling of the coolant at the bottoms of the battery modules 21 as much as possible.

In some embodiments, thermally conductive components may be arranged on the intermediate rod assemblies 1113 of the frame 111. The thermally conductive components are made of thermally conductive materials. The thermally conductive components may have regular shapes, such as cylinders, cubes, or cuboids, or have irregular shapes. The thermally conductive components may have shapes of islands and are arranged on each platform 102, respectively, and the thermally conductive components may pass through a separator 113 and extend into a liquid-cooling space 101 corresponding to another platform 102. In this way, thermal conduction can be achieved between liquid-cooling spaces 101 under the thermally conductive effects of the thermally conductive components, thereby ensuring the heat dissipation balance of the coolant in different liquid-cooling spaces 101.

As shown in FIG. 5, the frame 111 may further include reinforcing rib assemblies 1114 in one-to-one correspondence to the liquid-cooling spaces 101. Each reinforcing rib assembly 1114 is connected to a respective intermediate rod assembly 1113 and includes a respective plurality of reinforcing ribs arranged at intervals, and each reinforcing rib is flush with or lower than the respective plurality of intermediate rods in the predetermined direction.

The reinforcing rib assemblies 1114 can strengthen the structural strength of each platform 102 of the frame 111, thereby improving the capacity of each platform 102 of supporting the battery modules 21. Each reinforcing rib of the reinforcing rib assemblies 1114 may connect two respective adjacent intermediate rods of the intermediate rod assemblies 1113 to each other, so that the plurality of intermediate rods of each intermediate rod assembly 1113 are connected into a whole. An extending direction of the reinforcing ribs may be perpendicular to the extending direction of the intermediate rods.

Each reinforcing rib is flush with or lower than the respective plurality of intermediate rods, without affecting the fixation of the battery modules 21 on the platforms 102. Moreover, when the structural strengths of the reinforcing ribs are sufficient, gaps may be left between the reinforcing ribs and the battery modules 21, thereby facilitating the immersion coolant to contact with the bottoms of the battery modules 21 and achieve heat exchange.

In addition, each reinforcing rib assembly 1114 may include first reinforcing ribs and second reinforcing ribs having different extension directions. In this way, the structural strength of each platform 102 can be improved in different directions. In practice, the first reinforcing ribs and the second reinforcing ribs may be separated from each other, or may be connected together to form a whole. Furthermore, a respective distance between every two reinforcing ribs of the respective plurality of reinforcing ribs may be adjusted, so as to adapt to the filling amount of the coolant in different areas within a same liquid-cooling space 101, thereby optimizing the heat dissipation capacity in different areas within a same liquid-cooling space 101. For example, in the downstream areas for the coolant flowing in a liquid-cooling space 101, the number of arranged reinforcing ribs may be reduced to provide a larger filling space for the coolant, so that a sufficient amount of coolant can be filled under the bottoms of the battery modules 21, thereby ensuring the heat dissipation capacity of the coolant in the terminal segment of the flow path.

In some embodiments, as shown in FIG. 1, the fluid circulation structure 12 may further include a liquid replenishment pipeline 124, and the liquid replenishment pipeline 124 and the liquid-inlet pipeline 121 are connected to a same liquid-cooling space of the plurality of liquid-cooling spaces 101.

The liquid replenishment pipeline 124 may also be connected to the pipelines for supplying the coolant in the coolant circulation system, thereby injecting the coolant into the liquid-cooling spaces 101. The liquid replenishment pipeline 124 provides an independent channel for the coolant to enter the liquid-cooling spaces 101 in the box body 11. The coolant may be replenished into the liquid-cooling spaces 101 through the liquid replenishment pipeline 124, thereby increasing the amount of the coolant entering the liquid-cooling spaces 101. For example, when the temperatures of the cells 211 of the battery modules 21 accommodated in the box body 11 go out of the threshold range to a certain value, the coolant may be replenished through the liquid replenishment pipeline 124. Thus, in addition to the total capacity of the coolant currently flowing in the box body 11, a certain volume of the coolant is injected to improve the heat dissipation capacity. In addition, the flow rate of the coolant can be increased by increasing the fluid circulation rate, so as to take away the excessive heat in time.

As shown in FIG. 1, the distribution pipeline 131 and the series-flow pipelines 122 may be arranged on different lateral surfaces of the box body 11, respectively.

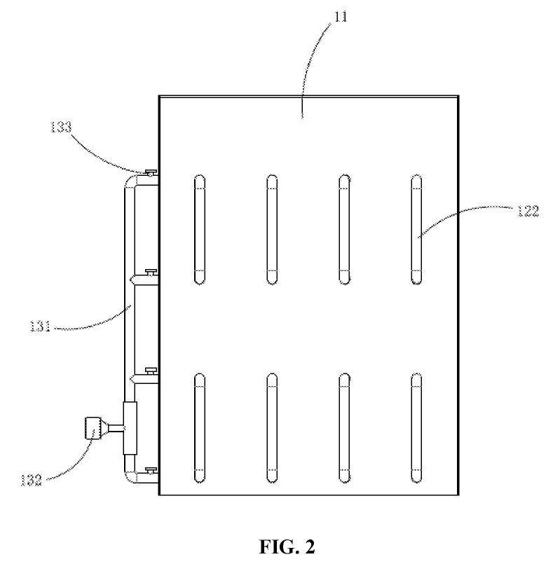

In this way, the mutual interference between the fluid circulation structure 12 and the liquid level adjustment structure 13 can be reduced, thereby preventing the fluctuations of liquid levels in the liquid-cooling spaces 101. As shown in FIG. 1 and FIG. 2, the distribution pipeline 131 is connected to a lateral surface of the box body 11 having a relatively large area. The distribution pipeline includes a main pipeline and a plurality of branch pipelines. The main pipeline is arranged along the predetermined direction. One respective end of each branch pipeline of the plurality of branch pipelines is in fluid communication with the main pipeline, and the other respective end of each branch pipeline is in fluid communication with a corresponding liquid-cooling space 101. Each fluid distribution unit 133 is arranged on a respective branch pipeline. The fluid control unit 132 is arranged on the main pipeline. The series-flow pipelines 122 are connected to the lateral surfaces of the box body 11 having relatively large areas. In practice, the distribution pipeline 131 may be arranged to space apart from the series-flow pipelines 122, so as to ensure the precise adjustment of liquid-level heights.

Some embodiments of the present disclosure provide an energy storage system including a plurality of battery modules 21 and the immersion liquid-cooling device as illustrated above. Each battery module 21 includes a plurality of cells 211 arranged sequentially, and each liquid-cooling space 101 of the box body 11 of the immersion liquid-cooling device accommodates at least one respective battery module 21.

The plurality of battery modules 21 are fixed inside the box body 11. Each liquid-cooling space 101 of the box body 11 may accommodate at least one respective battery module 21. The temperatures of the plurality of cells 211 of the at least one respective battery module 21 may be monitored by arranging thermocouples at pole pillars, and the temperatures of the plurality of cells 211 may be controlled using the immersion coolant. The immersion coolant may fully contact with the cells 211 to exchange heat, and take away the heat generated during the operation of the cells 211 in time, so as to realize effective heat dissipation of the battery modules 21.

In addition, as shown in FIG. 4, a heat-insulating material 213 may be provided between every two adjacent cells 211 of the battery modules 21.

The heat-insulating material 213 may be filled between every two adjacent cells 211, so as to prevent mutual influence due to mutual contact between the two adjacent cells 211, and prevent the thermal conduction between every two adjacent cells 211, thereby preventing the temperature control of the cells 211 from being affected.

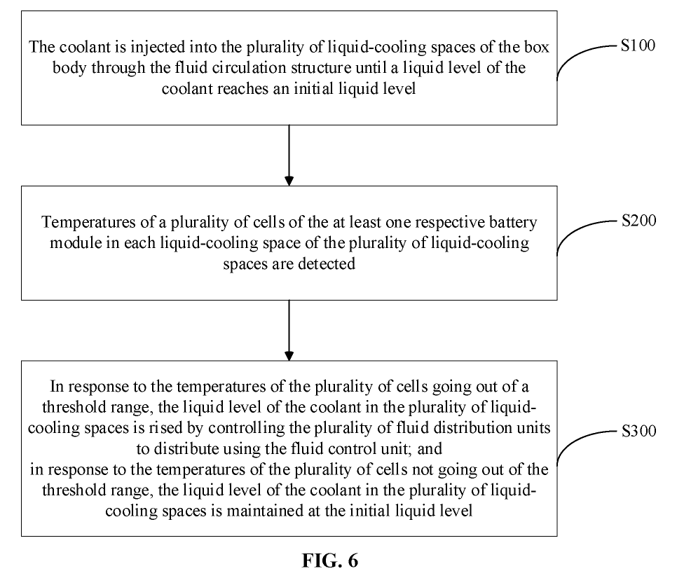

As shown in FIG. 6, some embodiments of the present disclosure provide a heat management method applied to the immersion liquid-cooling device as illustrated above.

At S100, the coolant is injected into the plurality of liquid-cooling spaces 101 of the box body 11 through the fluid circulation structure 12 until a liquid level of the coolant reaches an initial liquid level.

The initial liquid level may be set at 50% of the maximum height in the liquid-cooling spaces 101, that is, the liquid-cooling spaces 101 are semi-immersed, so as to adjust the liquid-level heights of the coolant based on the temperatures of the cells 211 later.

At S200, temperatures of the plurality of cells 211 of the at least one respective battery module 21 in each liquid-cooling space 101 is detected.

The temperatures of the cells 211 may be detected using temperature monitoring elements on the cells 211. For example, a thermocouple may be arranged on a pole pillar of a cell 211 to obtain the temperature information of this cell 211, so as to facilitate subsequent liquid-level adjustment.

At S300, in response to the temperatures of the plurality of cells 211 going out of a threshold range, rising the liquid level of the coolant in the plurality of liquid-cooling spaces 101 by controlling the plurality of fluid distribution units 133 to distribute using the fluid control unit 132; and in response to the temperatures of the plurality of cells 211 not going out of the threshold range, maintaining the liquid level of the coolant in the plurality of liquid-cooling spaces 101 at the initial liquid level.

That is to say, when the temperatures of the plurality of cells 211 go out of a threshold range, the liquid-level height of the immersion coolant in the liquid-cooling space 101 where the battery module 21 is located may be increased, thereby improving the heat dissipation capacity within the liquid-cooling space 101 and taking away the heat from the cells 211 in time. When the temperatures of the plurality of cells 211 do not go out of the threshold range, i.e. within a reasonable range, the coolant in the liquid-cooling space 101 is maintained at the initial liquid level.

In practice, taking the immersion liquid-cooling device in the energy storage system shown in FIG. 1 as an example, each liquid-cooling space 101 inside the box body 11 is semi-immersed by the immersion coolant, that is, 50% of the maximum height of each liquid-cooling space 101 is immersed. After the battery modules 21 start to charge and discharge, the coolant is injected into the box body 11 from the liquid-inlet pipeline 121, and realizes the unidirectional flow and heat exchange in the liquid-cooling spaces 101 through the series-flow pipelines 122. Since the heat dissipation capacity of the coolant gradually decreases as it continuously absorbs heat during flowing, the following control strategy may be implemented based on the temperature monitoring data of the cells 211:

(1) When the maximum temperature difference between the cells 211 of two battery modules 21 in the box body 11 is less than 2°C. (degrees Celsius), the fluid control unit 132 and the plurality of fluid distribution units 133 of the liquid level adjustment structure 13 do not perform fluid distribution, and the immersion heights of the coolant in the plurality of liquid-cooling spaces 101 remain unchanged.

(2) When the maximum temperature difference between the cells 211 of two battery modules 21 in the box body 11 is greater than 2°C. and less than 3°C., the fluid control unit 132 and the plurality of fluid distribution units 133 of the liquid level adjustment structure 13 are activated, and openings of the plurality of fluid distribution units 133 are adjusted, so that the liquid-level height of the coolant in a first-layer liquid-cooling space 101 (the liquid-cooling space at the top layer) is reduced by 15%, the liquid-level height of the coolant in a second-layer liquid-cooling space 101 remains unchanged, and the liquid-level heights of the coolant in a third-layer liquid-cooling space 101 and a fourth-layer liquid-cooling space 101 are increased by 5% and 10%, respectively.

(3) When the maximum temperature difference between the cells 211 of two battery modules 21 in the box body 11 is greater than 3°C., the fluid control unit 132 and the plurality of fluid distribution units 133 of the liquid level adjustment structure 13 are activated., and openings of the plurality of fluid distribution units 133 are adjusted, so that the liquid-level height of the coolant in the first-layer liquid-cooling space 101 (the liquid-cooling space at the top layer) is reduced by 30%, the liquid-level height of the coolant in a second-layer liquid-cooling space 101 remains unchanged, and the liquid-level heights of the coolant in a third-layer liquid-cooling space 101 and a fourth-layer liquid-cooling space 101 are increased by 10% and 20%, respectively.

(4) When the maximum temperature difference between the cells 211 of two battery modules 21 in the box body 11 exceeds 10°C., the coolant is replenished through the liquid replenishment pipeline 124. Besides the total capacity of the coolant currently flowing in the box body 11, additional coolant is injected by 10%, and the supply flow rate of the coolant at the liquid-inlet pipeline 121 is increased accordingly.

It is be noted that the above-mentioned control strategy is only an example of the actual control situation. When the temperatures of the cells 211 of the battery modules 21 in a certain liquid-cooling space 101 are abnormal, the liquid-level height or the flow rate of the immersion coolant in this liquid-cooling space 101 may be controlled individually, to improve the heat dissipation capacity of the coolant in this liquid-cooling space 101. For example, in order to control the flow rate of the coolant in each liquid-cooling space 101, a flow control valve may be provided in each pipeline of the fluid circulation structure 12. That is, flow control valves may be provided in the liquid-inlet pipelines 121, the series-flow pipelines 122, or the liquid-outlet pipelines 123, respectively, so as to realize precise control when it is necessary to adjust the flow rate of the coolant in some liquid-cooling spaces 101 individually.

Those skilled in the art shall understand that the above-mentioned embodiments are specific examples for implementing the present disclosure. In practice, various changes may be made in form and details without departing from the scope of the present disclosure.

What is claimed is:

1. An immersion liquid-cooling device, comprising:
a box body having a plurality of liquid-cooling spaces sequentially formed along a predetermined direction and isolated from each other, wherein each liquid-cooling space of the plurality of liquid-cooling spaces is configured to accommodate at least one respective battery module; and
a fluid circulation structure connected to the box body, wherein the fluid circulation structure includes a liquid-inlet pipeline for supplying a coolant, a series-flow pipeline for transferring the coolant, and a liquid-outlet pipeline for discharging the coolant, wherein one of two distal liquid-cooling spaces of the plurality of liquid-cooling spaces in the predetermined direction is in fluid communication with the liquid-inlet pipeline, the other of the two distal liquid-cooling spaces is in fluid communication with the liquid-outlet pipeline, and every two adjacent liquid-cooling spaces of the plurality of liquid-cooling spaces are in fluid communication with each other through the series-flow pipeline.

2. The immersion liquid-cooling device according to claim 1, further including a liquid level adjustment structure connected to the box body, wherein the liquid level adjustment structure includes a distribution pipeline in fluid communication with the plurality of liquid-cooling spaces, a fluid control unit, and a plurality of fluid distribution units, and wherein the fluid control unit and the plurality of fluid distribution units are arranged on the distribution pipeline, the plurality of fluid distribution units are in one-to-one correspondence to the plurality of liquid-cooling spaces, each fluid distribution unit of the plurality of fluid distribution units is configured to distribute the coolant to a respective liquid-cooling space, and the fluid control unit is configured to control an amount of the coolant distributed by each fluid distribution unit to the respective liquid-cooling space and to adjust a liquid level in the respective liquid-cooling space.

3. The immersion liquid-cooling device according to claim 1, wherein the liquid-inlet pipeline and the liquid-outlet pipeline are arranged on one of two lateral surfaces of the box body extending along a first direction or are arranged on the two lateral surfaces, respectively, and the first direction is perpendicular to an arrangement direction of a plurality of cells of the at least one respective battery module.

4. The immersion liquid-cooling device according to claim 3, wherein the fluid circulation structure includes a plurality of series-flow pipelines, each series-flow pipeline of the plurality of series-flow pipelines is configured to communicate two respective liquid-cooling spaces of the plurality of liquid-cooling spaces that are adjacent in the predetermined direction, and the plurality of series-flow pipelines are alternately arranged on the two lateral surfaces of the box body.

5. The immersion liquid-cooling device according to claim 3, wherein the fluid circulation structure includes a plurality of liquid-inlet pipelines, a plurality of liquid-outlet pipelines, and a plurality of series-flow pipelines that are arranged at intervals along the first direction, respectively.

6. The immersion liquid-cooling device according to claim 1, wherein the box body includes a frame, walls arranged on the frame and forming an enclosed space , and separators dividing the enclosed space into the plurality of liquid-cooling spaces, and wherein the frame has a plurality of platforms in one-to-one correspondence to the plurality of liquid-cooling spaces, each platform of the plurality of platforms has a respective hollow area and is configured to support the at least one respective battery module and separate the at least one respective battery module from a corresponding separator of the separators.

7. The immersion liquid-cooling device according to claim 6, wherein the frame includes a plurality of columns abutting on the walls, respectively, a plurality of connecting rod assemblies arranged along the predetermined direction and respectively connected to the plurality of columns, and intermediate rod assemblies in one-to-one correspondence to the plurality of liquid-cooling spaces; and
wherein each intermediate rod assembly of the intermediate rod assemblies is connected to a respective connecting rod assembly of the plurality of connecting rod assemblies and includes a respective plurality of intermediate rods arranged at intervals and configured to support the at least one respective battery module, and an extending direction of the respective plurality of intermediate rods is parallel to an arrangement direction of a plurality of cells of the at least one respective battery module.

8. The immersion liquid-cooling device according to claim 7, wherein the frame further includes reinforcing rib assemblies in one-to-one correspondence to the plurality of liquid-cooling spaces, wherein each reinforcing rib assembly of the reinforcing rib assemblies is connected to a respective intermediate rod assembly of the intermediate rod assemblies and includes a respective plurality of reinforcing ribs arranged at intervals, and each reinforcing rib of the respective plurality of reinforcing ribs is flush with or lower than the respective plurality of intermediate rods in the predetermined direction.

9. The immersion liquid-cooling device according to claim 6, wherein each separator of the separators has respective grooves formed on a respective surface of each separator bearing the coolant, and the respective grooves are configured for the coolant to flow; and
wherein each groove of the respective grooves has a respective curved shape or extends along a respective curved path.

10. The immersion liquid-cooling device according to claim 8, wherein each reinforcing rib assembly of the reinforcing rib assemblies includes respective first reinforcing ribs and respective second reinforcing ribs, and the respective first reinforcing ribs have an extension direction different from an extension direction of the respective second reinforcing ribs.

11. The immersion liquid-cooling device according to claim 1, wherein the fluid circulation structure further includes a liquid replenishment pipeline, and the liquid replenishment pipeline and the liquid-inlet pipeline are connected to a same liquid-cooling space of the plurality of liquid-cooling spaces.

12. An energy storage system, comprising:
a plurality of battery modules, wherein each battery module of the plurality of battery modules includes a respective plurality of cells; and
an immersion liquid-cooling device;
wherein the immersion liquid-cooling device comprises:
a box body having a plurality of liquid-cooling spaces sequentially formed along a predetermined direction and isolated from each other, wherein each liquid-cooling space of the plurality of liquid-cooling spaces is configured to accommodate at least one respective battery module; and
a fluid circulation structure connected to the box body, wherein the fluid circulation structure includes a liquid-inlet pipeline for supplying a coolant, a series-flow pipeline for transferring the coolant, and a liquid-outlet pipeline for discharging the coolant, wherein one of two distal liquid-cooling spaces of the plurality of liquid-cooling spaces in the predetermined direction is in fluid communication with the liquid-inlet pipeline, the other of the two distal liquid-cooling spaces is in fluid communication with the liquid-outlet pipeline, and every two adjacent liquid-cooling spaces of the plurality of liquid-cooling spaces are in fluid communication with each other through the series-flow pipeline;
wherein each liquid-cooling space of the plurality of liquid-cooling spaces of the box body is configured to accommodate at least one respective battery module of the plurality of battery modules.

13. The immersion liquid-cooling device according to claim 12, wherein the immersion liquid-cooling device further includes a liquid level adjustment structure connected to the box body, wherein the liquid level adjustment structure includes a distribution pipeline in fluid communication with the plurality of liquid-cooling spaces, a fluid control unit, and a plurality of fluid distribution units, and wherein the fluid control unit and the plurality of fluid distribution units are arranged on the distribution pipeline, the plurality of fluid distribution units are in one-to-one correspondence to the plurality of liquid-cooling spaces, each fluid distribution unit of the plurality of fluid distribution units is configured to distribute the coolant to a respective liquid-cooling space, and the fluid control unit is configured to control an amount of the coolant distributed by each fluid distribution unit to the respective liquid-cooling space and to adjust a liquid level in the respective liquid-cooling space.

14. The immersion liquid-cooling device according to claim 12, wherein the liquid-inlet pipeline and the liquid-outlet pipeline are arranged on one of two lateral surfaces of the box body extending along a first direction or are arranged on the two lateral surfaces, respectively, and the first direction is perpendicular to an arrangement direction of a plurality of cells of the at least one respective battery module.

15. The immersion liquid-cooling device according to claim 14, wherein the fluid circulation structure includes a plurality of series-flow pipelines, each series-flow pipeline of the plurality of series-flow pipelines is configured to communicate two respective liquid-cooling spaces of the plurality of liquid-cooling spaces that are adjacent in the predetermined direction, and the plurality of series-flow pipelines are alternately arranged on the two lateral surfaces of the box body.

16. The immersion liquid-cooling device according to claim 12, wherein the box body includes a frame, walls arranged on the frame and forming an enclosed space , and separators dividing the enclosed space into the plurality of liquid-cooling spaces, and wherein the frame has a plurality of platforms in one-to-one correspondence to the plurality of liquid-cooling spaces, each platform of the plurality of platforms has a respective hollow area and is configured to support the at least one respective battery module and separate the at least one respective battery module from a corresponding separator of the separators.

17. The immersion liquid-cooling device according to claim 16, wherein the frame includes a plurality of columns abutting on the walls, respectively, a plurality of connecting rod assemblies arranged along the predetermined direction and respectively connected to the plurality of columns, and intermediate rod assemblies in one-to-one correspondence to the plurality of liquid-cooling spaces; and
wherein each intermediate rod assembly of the intermediate rod assemblies is connected to a respective connecting rod assembly of the plurality of connecting rod assemblies and includes a respective plurality of intermediate rods arranged at intervals and configured to support the at least one respective battery module, and an extending direction of the respective plurality of intermediate rods is parallel to an arrangement direction of a plurality of cells of the at least one respective battery module.

18. The immersion liquid-cooling device according to claim 17, wherein the frame further includes reinforcing rib assemblies in one-to-one correspondence to the plurality of liquid-cooling spaces, wherein each reinforcing rib assembly of the reinforcing rib assemblies is connected to a respective intermediate rod assembly of the intermediate rod assemblies and includes a respective plurality of reinforcing ribs arranged at intervals, and each reinforcing rib of the respective plurality of reinforcing ribs is flush with or lower than the respective plurality of intermediate rods in the predetermined direction.

19. The immersion liquid-cooling device according to claim 16, wherein each separator of the separators has respective grooves formed on a respective surface of each separator bearing the coolant, and the respective grooves are configured for the coolant to flow; and
wherein each groove of the respective grooves has a respective curved shape or extends along a respective curved path.

20. The immersion liquid-cooling device according to claim 18, wherein each reinforcing rib assembly of the reinforcing rib assemblies includes respective first reinforcing ribs and respective second reinforcing ribs, and the respective first reinforcing ribs have an extension direction different from an extension direction of the respective second reinforcing ribs.
